(19) United States
(12) Patent Application Publication
(10) Pub. No.: US 2009/0309642 A1
(43) Pub. Date: Dec. 17, 2009

(54) SIGNAL DELAY DEVICES, CLOCK DISTRIBUTION NETWORKS, AND METHODS FOR DELAYING A SIGNAL

(75) Inventor: Jong-sun KIM, Seongnam-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/423,030

(22) Filed: Apr. 14, 2009

(30) Foreign Application Priority Data
Jun. 12, 2008 (KR) 10-2008-0055431

(51) Int. Cl. H03H 11/26

(52) U.S. Cl. 327/261

(57) ABSTRACT

In one aspect, a signal delay device includes an inverter circuit, a positive feedback circuit, and a programmable element. The inverter circuit is connected between an input node and an output node, and the positive feedback circuit is connected between the output node and the inverter circuit. The programmable element controls the positive feedback circuit to set a voltage transfer characteristic from the input node to the output node.

### BACKGROUND OF THE INVENTION

1. Field of the Invention

The present invention generally relates to electronic devices, and more particularly, the present invention relates to signal delay devices, to clock distribution networks, and to methods of delaying a signal.

2. Description of the Related Art

Signal delay devices are utilized in a variety of applications, including, for example, the clock distribution networks of semiconductor memory devices. Typically, the signal delay devices are comprised of inverter circuits having an inherent delay in the switching action thereof.

FIG. 1 illustrates an example of a conventional delay device. In this example, a simple inverter circuit is formed by PMOS and NMOS transistors and connected in series between a supply voltage and ground. As is well understood in the art, a logic transition at the input In (e.g., from HIGH to LOW) will result in an opposite logic transition at the output Out (e.g., from LOW to HIGH. The output transition is delayed relative to the input transition due to non-ideal characteristics of the PMOS and NMOS transistors. In particular, the voltage transfer characteristics of the inverter circuit are influenced by parasitic resistive and capacitive components which introduce inherent resistive-capacitive (RC) time constants.

In the meantime, it sometimes becomes necessary to finely adjust the voltage transfer characteristics of a delay circuit, especially in complex clock distribution networks. Such adjustment is conventional realized by altering the RC time constants of the delay circuit.

That is, referring again to FIG. 1, resistors R1 and R2 and capacitors C1 and C2 may be included in the delay circuit as shown in the figure. In addition, the resistors R1 and R2 may be selectively by-passed using transistors T1 and T2, while the capacitors may be selectively disabled using transistors T3 and T4. By controlling the ON-OFF states of the transistors T1-T4, the RC time constants of the delay device may be adjusted to manipulate the voltage transfer characteristics thereof. For example, additional delay may be introduced, or the duty ratio of the output signal may be altered.

However, RC-based control of voltage transfer characteristics suffers from a number of drawbacks. For example, power consumption is relatively high, and it is generally difficult to achieve sufficiently robust and precise control characteristics.

### SUMMARY OF THE INVENTION

According to one aspect of the present invention, a signal delay device is provided which includes an inverter circuit connected between an input node and an output node, a positive feedback circuit connected between the output node and the inverter circuit, and a programmable element which controls the positive feedback circuit to set a voltage transfer characteristic from the input node to the output node.

According to another aspect of the present invention, a signal delay device is provided which includes an inverter circuit, and programmable positive feedback paths connected to an output node of the inverter circuit.

According to yet another aspect of the present invention, a signal delay device is provided which includes an inverter circuit and a programmable positive feedback path which selectively controls a voltage transfer characteristic of the inverter circuit.

According to still another aspect of the present invention, a clock distribution network is provided which includes a plurality of a clock distribution lines which receive a common internal clock signal, where at least one of the clock distributions lines includes a signal delay. The signal delay device includes an inverter circuit connected between an input node and an output node, a positive feedback circuit connected between the output node and the inverter circuit, and a programmable element which controls the positive feedback circuit to set a voltage transfer characteristic from the input node to the output node.

According to another aspect of the present invention, a method for delaying a signal is provided which includes applying the signal to an inverter circuit, and controlling a programmable positive feedback path from an output node of the inverter circuit to set a voltage transfer characteristics of the inverter circuit.

### BRIEF DESCRIPTION OF THE DRAWINGS

The above and other aspect and features of the present invention will become readily apparent from the detailed description that follows, with reference to the accompanying drawings, in which:

FIG. 1 is a circuit diagram of a conventional signal delay device;

FIG. 2 is a block diagram of a signal delay device according to an embodiment of the present invention;

FIG. 3 is a circuit diagram of a signal delay device according to another embodiment of the present invention;

FIG. 4 is a graph for use in describing voltage transfer characteristics of the signal delay device of FIG. 3;

FIG. 5 is a circuit diagram of a signal delay device according to another embodiment of the present invention; and

FIG. 6 is a diagram of a clock distribution network which utilizes one or more signal delay devices according to one or more embodiments of the present invention.

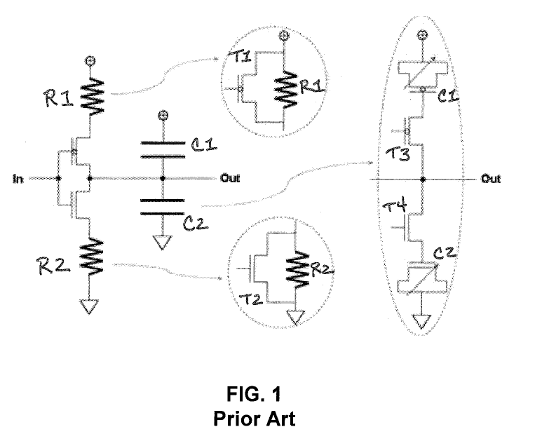

### DETAILED DESCRIPTION OF PREFERRED EMBODIMENTS

The present invention will now be described by way of preferred, but non-limiting, embodiments of the invention.

For ease of understanding and to avoid redundancy, like reference numbers refer to the same or similar elements throughout the drawings. Also, while the drawings contain a number of circuit diagrams, it will be understood from the nature of electrical circuits that when an element is described as being connected to another element, it can be directly connected the other element or one or more intervening elements may be present. In contrast, if an element is referred to as being “directly connected to” another element, then no intervening elements are present. Other words used to describe the relationship between elements should be interpreted in a like fashion (e.g., “between” versus “directly between,” “adjacent” versus “directly adjacent,” “connected” versus “directly connected,” etc.).

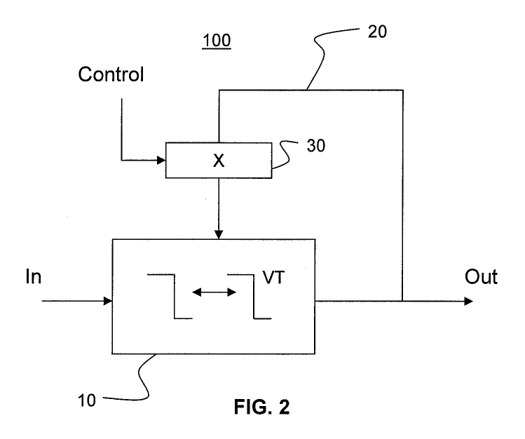

FIG. 2 is a block diagram of a signal delay device according to one or more embodiments of the present invention.

Referring to FIG. 2, a signal delay device 100 includes an inverter circuit 10, a positive feedback circuit 20, and a programmable element 30. The inverter circuit 10, which may include one or more inverters, is connected between an input node In and an output node Out.

The positive feedback circuit 20 is connected between the output node Out and the inverter 10. When enabled, the positive feedback circuit 20 influences the voltage transfer characteristics of the inverter circuit 10.

The programmable element, which operates in response to a control signal Control, is connected to enable or disable the positive feedback circuit 20.

In operation, voltage transfer characteristics VT of the inverter circuit 10 are operatively responsive to the positive feedback circuit 20, and the positive feedback circuit 20 is operatively responsive to the programmable element 30. In this manner, the programmable element 30 may be utilized to adjust the voltage transfer characteristics VT of the signal delay device 100.

For example, the positive feedback circuit 20 may include voltage pull-up and voltage pull-down elements which are enabled and disabled according to a voltage at the output node Out. Further, the programmable element 30 may include elements which are responsive to the control signal Control to enable and disable the voltage pull-up and voltage pull-down elements. As will be explained below in connection with the exemplary embodiments that follow, utilizing positive feedback in this manner allows for control of the voltage transfer characteristics of the signal delay device.

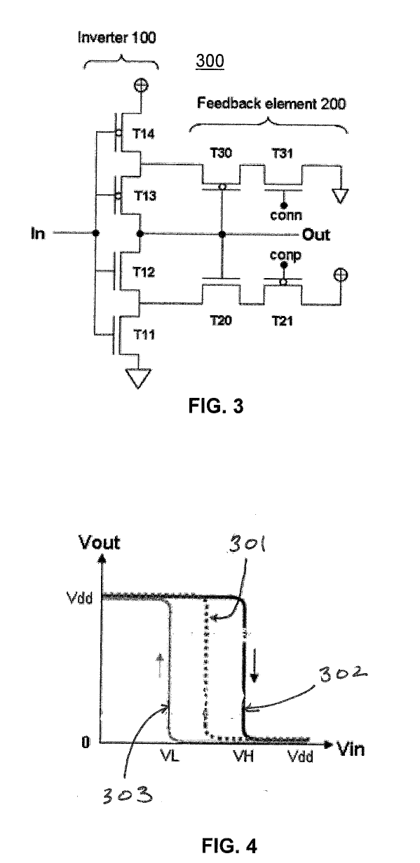

A signal delay device according to an embodiment of the present invention will now be described with reference to FIG. 3 of the drawings.

Referring to FIG. 3, the signal delay device 300 of this example includes an inverter 100 and a feedback element 200.

The inverter 100 includes PMOS transistors T14 and T13 connected in series between a supply voltage and an output node Out, and NMOS transistors T12 and T11 connected in series between the output node Out and ground. An input node In is commonly connected to gates of the transistors T14, T13, T12 and T11.

The feedback element 200 includes a PMOS transistor T30 and an NMOS transistor T31 connected in series between the connection node of transistors T14 and T13 and ground, and an NMOS transistor T20 and a PMOS transistor T21 connected in series between the connection node of transistors T12 and T11 and a supply voltage (e.g., VCC or Vdd). The output node Out of the inverter 100 is commonly connected to the gates of the transistors T30 and T20. A control signal “conn” is applied to the gate of the transistor T31, and a control signal “conp” is applied to the gate of the transistor T21.

As will be described in more detail below, the transistor T30 and T20 effectively function as pull-up and pull-down devices, respectively, with respect to the output node Out. The transistor T31 functions as a programmable element to control (enable or disable) the pull-up feedback device (transistor T30), while the transistor T21 functions as a programmable element to control (enable or disable) the pull-down feedback device (transistor T20).

The operation of signal delay device of FIG. 3 will now be described with reference to the voltage diagram of FIG. 4. The operation will be described with respect to each of the operational states identified in the Table 1 below:

TABLE 1

| State | conn | conp | T31 | T21 |
|---|---|---|---|---|
| I | LOW | HIGH | OFF | OFF |
| II | LOW | LOW | OFF | ON |
| III | HIGH | HIGH | ON | OFF |
| IV | HIGH | LOW | ON | ON |

Referring collectively to FIGS. 3 and 4, the transistors T31 and T21 are both OFF in State I. As such, the feedback elements (transistors T30 and T20) are disabled. In this state, the voltage at the output node Out is not influenced, and the device operates as a normal inverter having the voltage characteristic curve 301 shown in FIG. 4.

In State II, the transistor T31 is OFF, and the transistor T21 is ON. Assume here that the voltage at the input node In is logic LOW and the voltage at the output node Out is logic HIGH. In this condition, pull-down transistor T30 is OFF, pull-up transistor T20 is ON, and the supply voltage is applied to the drain of transistor T11 (since transistor T21 is ON). When the voltage at the input node In begins to transition from logic LOW to logic HIGH, the supply voltage VCC at the source of the transistor T12 delays the turn-on time of the transistor T12. As such, the grounding of the output node Out to LOW through transistors T12 and T11 is delayed.

Assume now that the voltage at the input node In is logic HIGH and the voltage at the output node Out is logic LOW in State II. In this condition, pull-up transistor T20 is OFF, and pull-down transistor T30 is ON. However, since transistor T31 is OFF, the ON-state of the transistor T30 does not pass the ground voltage to the inverter 100. As such, there is not impact on the delay time of the output node Out voltage transition (from LOW to HIGH) when the input node transitions from logic HIGH to logic LOW.

Thus, in State II, the embodiment is characterized by extra delay time when the input node In transitions from LOW to HIGH, and no influence on delay time when the input node In transitions from HIGH to LOW. This causes the voltage transfer characteristics to shift to the right in FIG. 4, as represented by the voltage characteristic curve 302.

In State III, the transistor T31 is ON, and the transistor T21 is OFF. Assume here that the voltage at the input node In is logic HIGH and the voltage at the output node Out is logic LOW. In this condition, pull-up transistor T20 is OFF, pull-down transistor T30 is ON, and the ground voltage is applied to the drain of transistor T14 (since transistor T31 is ON). When the voltage at the input node In begins to transition from logic HIGH to logic LOW, the ground voltage at the source of the transistor T13 delays the turn-on time of the transistor T13. As such, the rise of the output node Out to HIGH through the transistors T14 and T13 is delayed.

Assume now that the voltage at the input node In is logic LOW and the voltage at the output node Out is logic HIGH in State III. In this condition, pull-down transistor T30 is OFF, and pull-up transistor T20 is ON. However, since transistor T21 is OFF, the ON-state of the transistor T20 does not pass the supply voltage VCC to the inverter 100. As such, there is not impact on the delay time of the output node Out voltage transition (from HIGH to LOW) when the input node transitions from logic LOW to logic HIGH.

Thus, in State III, the embodiment is characterized by extra delay time when the input node In transitions from HIGH to LOW, and no influence on delay time when the input node In transitions from LOW to HIGH. This causes the voltage transfer characteristics to shift to the left in FIG. 4, as represented by the voltage characteristic curve 303.

In State IV, both control transistors T31 and T21 are ON. As such, the ground voltage is applied to the source of transistor T14 when the voltage of output node Out is logic LOW, and the supply voltage Vdd is applied to the drain of the transistor T11 when the voltage of the output node Out is logic HIGH. As will be apparent from the above discussion of States II and III, the result is to introduce delay both when the voltage at the input node In transitions from LOW to HIGH, and when the voltage at the input node IN transitions from HIGH to LOW. The result is a hysteresis voltage characteristic as represented by voltage characteristic curves 302 and 303 in FIG. 4. Thus, in this state, the delay device of this embodiment functions like a Schmitt Trigger to prevent noisy input signals from causing improper transitions at the output node.

As described above, according to the first embodiment of the present invention, programmable elements (e.g., the transistors T31 and T21) are utilized to selectively enable and disable pull-up and pull-down positive feedback elements (e.g., the transistors T30 and T20) connected at the output of the signal delay device. This allows for dynamic control of the voltage transfer characteristics (e.g., delay time, duty ratio, and hysteresis characteristics) of the signal delay device.

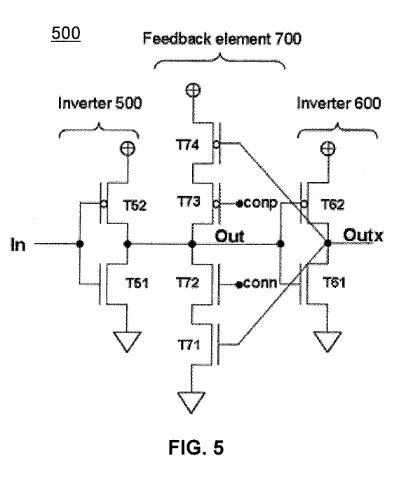

A signal delay device according to another non-limiting embodiment of the present invention will now be described with reference to FIG. 5 of the drawings.

Referring to FIG. 5, the signal delay device 500 of this example includes first and second inverters 500 and 600, and a feedback element 700.

The first inverter 500 includes a PMOS transistor T52 and an NMOS transistor T51 connected in series between a supply voltage and ground, with an input node In commonly connected to the gates of the transistors T52 and T51. The output node of the first inverter 500 is referred to herein as an intermediate output node Out.

The second inverter 600 includes a PMOS transistor T62 and an NMOS transistor T61 connected in series between the supply voltage and ground, with the intermediate output node Out commonly connected to the gates of the transistors T62 and T61. In other words, the output of the first inverter 500 is connected to the input of the second inverter 600. The output node Outx of the second inverter 600 is defined at the connection between the transistors T62 and T61.

The feedback element 700 includes PMOS transistors T74 and T73 connected in series between the supply voltage and the intermediate output node Out, and NMOS transistors T72 and T71 connected in series between the intermediate output node Out and ground. The gates of the transistors T74 and T71 are connected to the output node Outx, thereby establishing positive feedback. The gates of the transistors T73 and T72 receive control signals “conp” and “conn”, respectively, to thereby control the ON/OFF states thereof.

As will be described in more detail below, the transistor T74 and T71 effectively function as pull-up and pull-down devices, respectively, with respect to the intermediate output node Out. The transistor T73 functions as a programmable element to control the pull-up feedback element (transistor T74), while the transistor T72 functions as a programmable element to control the pull-down feedback element (transistor T71).

The operation of signal delay device of FIG. 5 will now be described with respect to each of the operational states identified in the Table 2 below:

TABLE 2

| State | conn | conp | T72 | T73 |
|---|---|---|---|---|
| I | LOW | HIGH | OFF | OFF |
| II | HIGH | HIGH | ON | OFF |
| III | LOW | LOW | OFF | ON |
| IV | HIGH | LOW | ON | ON |

Referring to FIG. 5, the transistors T72 and T73 are both OFF in State I. As such, the feedback elements (transistors T71 and T73) are disabled. In this state, the voltage at the intermediated output node Out is not influenced by the positive feedback elements T74 and T71, and the device operates as a normal delay device having series connected inverters.

In State II, the transistor T72 is ON, and the transistor T73 is OFF. Assume here that the voltage at the input node In is logic HIGH, the voltage at the intermediate output node Out is logic LOW, and the voltage at the output node Out is logic HIGH. In this condition, the pull-up transistor T74 is OFF, the pull-down transistor T71 is ON, and the ground voltage is applied to the intermediate output node Out via the transistors T71 and T72. When the voltage at the input node In then begins to transition from logic HIGH to logic LOW, the ground voltage at the intermediate output node Out delays the eventual transition of the output node Outx from logic HIGH to logic LOW.

Assume now that the voltage at the input node In is logic LOW and the voltage at the output node Outx is logic LOW in State II. In this condition, pull-down transistor T71 is OFF, and pull-up transistor T74 is ON. However, since transistor T73 is OFF (since comp is HIGH), the supply voltage VCC is not supplied to the intermediate output node Out. As such, there is not impact on the delay time of the output node Out voltage transition (from LOW to HIGH) when the input node transitions from logic LOW to logic HIGH.

Thus, in State II, the embodiment is characterized by extra delay time when the input node In transitions from HIGH to LOW, and no influence on delay time when the input node In transitions from LOW to HIGH.

In State III, the transistor T72 is OFF, and the transistor T73 is ON. Assume here that the voltage at the input node In is logic LOW, the voltage at the intermediate output node Out is logic HIGH, and the voltage at the output node Out is logic LOW. In this condition, the pull-up transistor T74 is ON, the pull-down transistor T71 is OFF, and the supply voltage VCC is applied to the intermediate output node Out via the transistors T73 and T74. When the voltage at the input node In then begins to transition from logic LOW to logic HIGH, the supply voltage VCC at the intermediate output node Out delays the eventual transition of the output node Outx from logic LOW to logic HIGH.

Assume now that the voltage at the input node In is logic HIGH and the voltage at the output node Outx is logic HIGH in State III. In this condition, pull-down transistor T71 is ON, and pull-up transistor T74 is OFF. However, since transistor T72 is OFF (since “conn” is LOW), the ground voltage is not supplied to the intermediate output node Out. As such, there is no impact on the delay time of the output node Out voltage transition (from HIGH to LOW) when the input node transitions from logic HIGH to logic LOW.

Thus, in State III, the embodiment is characterized by extra delay time when the input node In transitions from LOW to HIGH, and no influence on delay time when the input node In transitions from HIGH to LOW.

In State IV, both control transistors T72 and T73 are ON. As such, the ground voltage is applied to the intermediate output node Out when the voltage of output node Outx is logic HIGH, and the supply voltage VCC is applied to the intermediate output node Out when the voltage of the output node Outx is logic LOW. As will be apparent from the above discussion of States II and III, the result is to introduce delay both when the voltage at the input node In transitions from LOW to HIGH, and when the voltage at the input node IN transitions from HIGH to LOW. The result is a hysteresis voltage characteristic which may be utilized to prevent noisy input signals from causing improper transitions at the output node.

In the embodiments described above, the programmable elements are each implemented as a single transistor to realize one-bit (ON/OFF) digital control. For example, in the embodiment of FIG. 3, either no voltage or the ground voltage is applied to the drain of transistor T14, and either no voltage or the supply voltage VCC is applied to the drain of transistor T11. However, the embodiments are not limited in this respect. For example, in the case of the embodiment of FIG. 3, a multi-bit digital control or linear control scheme may be implemented in which a variety of different voltages (e.g., between ground and VCC inclusive) are selectively applied to the drains of the transistors T14 and T11. This allows for even more precise dynamic control of the voltage transfer characteristics of the signal delay device. The embodiment of FIG. 5 may be similarly modified.

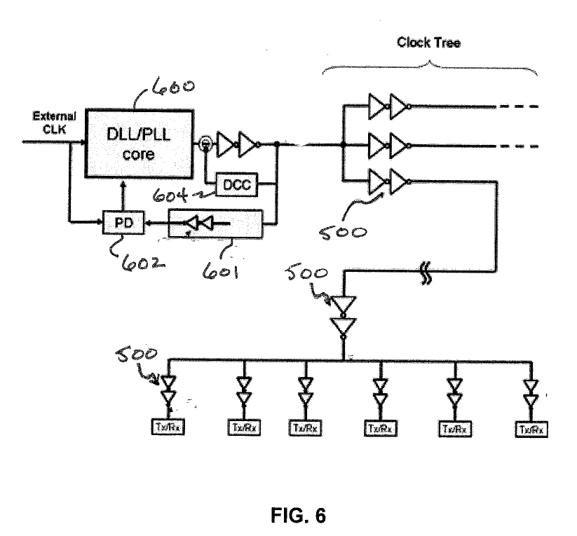

FIG. 6 is a diagram illustrating a clock distribution network of a semiconductor device. In the example of FIG. 6, the clock distribution circuit includes a plurality of delay devices 500 corresponding to the embodiment of previously described FIG. 5. Although not shown in FIG. 5, each of the delay devices 500 is supplied with control signals “conn” and “conp” to thereby control the voltage transfer characteristics thereof, i.e., to the control the delay time and/or duty cycle and/or hysteresis characteristic of each delay device 500.

Referring to FIG. 6, the clock distribution network includes a DLL/PLL core 600 (i.e., a delayed locked loop/phase locked loop circuit) which receives an external clock CLK. The output of the DLL/PLL core is subjected to duty cycle correction (DCC) and passed through an initial delay element which outputs an internal clock signal. That is, the internal clock signal is applied to a DCC circuit 604 which corrects the duty cycle of the thereof, typically to a 50:50 duty cycle (logic HIGH to logic LOW). The DLL/PLL core 600 is driven by the output a phase detector PD 603 which compares a phase of the external clock signal and a phase of an output signal from a clock tree replica path 601.

The internal clock signal is distributed to a number of different clock trees which terminate at transmitter/receiver Tx/Rx circuits of various functional blocks of the semiconductor device.

Each of the clock trees includes one or more inverter circuits functioning as signal delay devices. In the embodiment of FIG. 6, at least one of the signal delay devices corresponds to the signal delay device of FIG. 5. As such, voltage transfer characteristics of the clock signal can be readily adjusted in response to the control signals “conn” and “conp”. Alternately, or in addition, at least one of the signal delay devices may be configured according to the embodiments of FIGS. 2 and 3 described previously.

While the present invention has been particularly shown and described with reference to exemplary embodiments thereof, it will be understood by those of ordinary skill in the art that various changes in form and details may be made therein without departing from the spirit and scope of the invention as defined by the appended claims and their equivalents.

What is claimed is:

1. A signal delay device, comprising:
an inverter circuit connected between an input node and an output node;
a positive feedback circuit connected between the output node and the inverter circuit; and
a programmable element which controls the positive feedback circuit to set a voltage transfer characteristic from the input node to the output node.

2. The signal delay device of claim 1, wherein the programmable element sets a duty ratio of an output signal at the output node.

3. The signal delay device of claim 1, wherein the programmable element sets a delay from the input node to the output node.

4. The signal delay device of claim 1, wherein the programmable element sets a hysteresis voltage transfer characteristic between the input node and the output node.

5. The signal delay device of claim 1, wherein the programmable element is responsive to a control signal to enable and disable the positive feedback circuit.

6. The signal delay device of claim 1, wherein the positive feedback circuit includes a pull-up transistor and a pull-down transistor each gated to the output node.

7. The signal delay device of claim 6, wherein the programmable element includes a first transistor which enables and disables the pull-up transistor, and a second transistor which enables and disables the pull-down transistor.

8. The signal delay device of claim 1, wherein the inverter circuit includes a first inverter connected between the input node and an intermediate node, and a second inverter connected between the intermediate node and the output node, and
wherein the positive feedback circuit is connected between the output node and the intermediate node.

9. The signal delay device of claim 8, wherein the positive feedback circuit includes a pull-up transistor connected to the intermediate node and gated to the output node, and a pull-down transistor connected to the intermediate node and gated to the output node.

10. The signal delay device of claim 9, wherein the programmable element enables and disables the pull-up and pull-down transistors.

11. The signal delay device of claim 9, wherein the programmable element includes a first transistor which enables and disables the pull-up transistor, and a second transistor which enables and disables the pull-down transistor.

12. The signal delay device of claim 1, wherein the inverter circuit includes a first plurality of transistors connected in series between a first reference voltage and the output node, and a second plurality of transistors connected in series between a second reference voltage and the output node, and
wherein the positive feedback circuit includes a pull-up transistor gated to the output node and connected to a source/drain interface among the first plurality of transistors, and a pull-down transistor gated to the output node and connected to a source/drain interface among the second plurality of transistors.

13. The signal delay device of claim 12, wherein the programmable element enables and disables the pull-up and pull-down transistors.

14. The signal delay device of claim 12, wherein the programmable element includes a first transistor which enables and disables the pull-up transistor, and a second transistor which enables and disables the pull-down transistor.

15. A signal delay device comprising an inverter circuit, and programmable positive feedback paths connected to an output node of the inverter circuit.

16. The signal delay device of claim 15, wherein the programmable positive feedback paths are configured to selectively set a voltage transfer characteristic of the inverter circuit.

17. The signal delay device of claim 16, wherein the voltage transfer characteristic includes at least one of a delay time and a hysteresis characteristic of the inverter circuit.

18. The signal delay device of claim 16, wherein the programmable positive feedback paths include selectively enabled voltage pull-up and voltage pull-down devices, respectively.

19. A signal delay device comprising an inverter circuit and a programmable positive feedback path which selectively controls a voltage transfer characteristic of the inverter circuit.

20. A clock distribution network comprising a plurality of a clock distribution lines which receive a common internal clock signal, wherein at least one of the clock distributions lines includes a signal delay device comprising:
an inverter circuit connected between an input node and an output node;
a positive feedback circuit connected between the output node and the inverter circuit; and
a programmable element which controls the positive feedback circuit to set a voltage transfer characteristic from the input node to the output node.

21. The clock distribution network of claim 20, wherein the programmable element sets a duty ratio of an output clock signal at the output node.

22. The clock distribution network of claim 20, wherein the programmable element sets a clock signal delay time from the input node to the output node.

23. The clock distribution network of claim 20, wherein the programmable element sets a hysteresis voltage transfer characteristic between the input node and the output node.

24. The clock distribution network of claim 20, wherein the programmable element is responsive to a control signal to enable and disable the positive feedback circuit.

25. A method for delaying a signal, comprising applying the signal to an inverter circuit, and controlling a programmable positive feedback path from an output node of the inverter circuit to set a voltage transfer characteristics of the inverter circuit.
